(19) United States
(12) Patent Application Publication
(10) Pub. No.: US 2011/0298011 A1
(43) Pub. Date: Dec. 8, 2011

(54) Semiconductor Memory Device And System Having Stacked Semiconductor Layers

(75) Inventors: Sang-bo Lee, Yongin-si (KR); Kye-hyun Kyung, Yongin-si (KR)

(73) Assignee: SAMSUNG ELECTRONICS CO., LTD., Suwon-si (KR)

(21) Appl. No.: 13/151,691

(22) Filed: Jun. 2, 2011

(30) Foreign Application Priority Data
Jun. 3, 2010 (KR) 10-2010-0052369

(51) Int. Cl. H01L 25/03

(52) U.S. Cl. 257/204; 257/E25.002

(57) ABSTRACT

Example embodiments relate to a semiconductor memory device and a system in which a plurality of semiconductor layers are stacked on each other. A 3-dimensional (3D) semiconductor memory device may include a plurality of semiconductor layers that are stacked on each other. The plurality of semiconductor layers may have the same memory cell structure. The 3D semiconductor memory device may include a first memory region including at least one semiconductor layer for storing system data and a second memory region including at least one semiconductor layer for storing data aside from the system data. The system data may include at least one piece of data selected from the group consisting of a booting code, a system code, and application software.

### CROSS-REFERENCE TO RELATED APPLICATION

This application claims priority under 35 U.S.C. §119 to Korean Patent Application No. 10-2010-0052369, filed on Jun. 3, 2010 with the Korean Intellectual Property Office, the disclosure of which is incorporated herein in its entirety by reference.

### BACKGROUND

Example embodiments of the inventive concepts relate to a semiconductor memory device and system, and more particularly, to a semiconductor memory device and system having a stacked structure.

A system using a semiconductor memory includes a main memory for transmitting and receiving information to and from a processor, and a storage unit for storing relatively large capacity data.

A dynamic random access memory (DRAM) may be used as the main memory and may be disposed relatively close to the processor to process data. However, a DRAM has a relatively small data storage capacity and is relatively expensive, and thus, mainly stores important information such as a system operating system. Since just a few bits of error in such a main memory may broadly affect operations of a system, faulty bits should be avoided.

A storage unit such as a hard disk drive or a solid state disk (SSD) may consume more time to read data from the processor, compared to the main memory, but this storage unit is relatively cheap, and thus, is used to store relatively large capacity data. An example of a relatively large capacity data is a digital image file, such as a document, a picture, or a moving image. Generally, when a few faulty bits are included in the storage unit, the quality of an object expressed by the data may deteriorate. However, it is relatively difficult for most users to recognize regions corresponding to the faulty bits, and such faulty bits do not affect operations of the system.

With the development of electronic devices, the capacity and operating speed of a semiconductor memory device for storing data have been increasing. Accordingly, in order to increase the capacity of the semiconductor memory device, a method of stacking a 3-dimensional (3D) semiconductor layer on a substrate is being studied. However, productivity may decrease while manufacturing a memory, because a memory is discarded if a faulty bit is generated or the number of faulty bits exceeds a threshold value, specifically if a faulty bit is generated in a layer of stacked layers in the memory.

### SUMMARY

Example embodiments of the inventive concepts relate to a semiconductor memory device, module, system, manufacturing method, and/or computer system, which may prevent a yield or productivity of a 3-dimensional (3D) memory (in which a plurality of semiconductor layers are stacked on each other) from deteriorating while improving an operating speed of a system using the 3D memory.

According to a non-limiting aspect of the inventive concepts, a 3D semiconductor memory device (in which a plurality of semiconductor layers are stacked on each other and have the same memory cell structure) may include a first memory region including at least one semiconductor layer configured for storing system data; and a second memory region including another at least one semiconductor layer configured for storing data aside from the system data, wherein the system data includes at least one piece of data selected from the group consisting of a booting code, a system code, and application software.

According to another non-limiting aspect of the inventive concepts, a 3D semiconductor memory device having a stacked structure may include a first memory region including at least one semiconductor layer configured for storing system data; and a second memory region having the same memory cell structure as the first memory region and including at least one semiconductor layer configured for storing data aside from the system data, wherein at least one semiconductor layer in which a faulty bit is not generated from among a plurality of semiconductor layers is set in (or designated as forming) the first memory region.

According to another non-limiting aspect of the inventive concepts, a 3D semiconductor memory device having a stacked structure may include a first memory region including at least one semiconductor layer configured for storing system data; and a second memory region including at least one semiconductor layer configured for storing data aside from the system data, wherein each of the at least one semiconductor layer of the first and second memory regions may includes a normal cell array and a redundancy cell array, and a ratio of the redundancy cell array to the normal cell array of the at least one semiconductor layer of the first memory region is higher than that of the second memory region.

According to another non-limiting aspect of the inventive concepts, a memory module may include at least one semiconductor memory device, wherein the at least one semiconductor memory device may have a 3D stacked structure of a plurality of semiconductor layers and including a first memory region including at least one semiconductor layer configured for storing system data; and a second memory region having the same memory structure as the first memory region and including at least one semiconductor layer configured for storing data aside from the system data.

According to another non-limiting aspect of the inventive concepts, a memory system may include a memory controller; and a memory module in which at least one semiconductor memory device is disposed, wherein the at least one semiconductor memory device has a 3D stacked structure of a plurality of semiconductor layers and includes a first memory region including at least one semiconductor layer configured for storing system data; and a second memory region having the same memory structure as the first memory region and including at least one semiconductor layer configured for storing data aside from the system data.

According to another non-limiting aspect of the inventive concepts, a computer system may include a central processing unit; a 3D semiconductor memory device in which a plurality of semiconductor layers are stacked on each other; and a nonvolatile memory device for storing large capacity data, wherein the 3D semiconductor memory device may include a first memory region including at least one semiconductor layer configured for storing system data; and a second memory region having the same memory structure as the first memory region and including at least one semiconductor layer configured for storing data aside from the system data.

### BRIEF DESCRIPTION OF THE DRAWINGS

Example embodiments of the inventive concepts may be more clearly understood when the following detailed description is taken in conjunction with the accompanying drawings in which:

FIG. 1 is a diagram of a 3-dimensional (3D) semiconductor memory device according to a non-limiting embodiment of the inventive concepts;

FIG. 2 is a diagram of the 3D semiconductor memory device of FIG. 1, according to a modified embodiment of the inventive concepts;

FIG. 3 is a diagram of the 3D semiconductor memory device of FIG. 1, according to another modified embodiment of the inventive concepts;

FIG. 4 is a diagram of the 3D semiconductor memory device of FIG. 1 realized as a dynamic random access memory (DRAM);

FIG. 5 is a diagram of a 3D semiconductor memory device according to another non-limiting embodiment of the inventive concepts;

FIG. 6 is a block diagram of semiconductor layers of the 3D semiconductor memory device of FIG. 5, according to a non-limiting embodiment of the inventive concepts;

FIG. 7 is a diagram of layer identification (ID) registers of the semiconductor layers of FIG. 6, realized as electric fuses;

FIG. 8 is a block diagram of semiconductor layers of the 3D semiconductor memory device of FIG. 5, according to another non-limiting embodiment of the inventive concepts;

FIGS. 9 and 10 are diagrams of 3D semiconductor memory devices according to other non-limiting embodiments of the inventive concepts;

FIGS. 11 and 12 are diagrams of methods of manufacturing a 3D semiconductor memory device, according to non-limiting embodiments of the inventive concepts;

FIGS. 13A and 13B are diagrams of packaged 3D semiconductor memory devices according to non-limiting embodiments of the inventive concepts;

FIG. 14 is a diagram of a memory system using a 3D semiconductor memory device, according to a non-limiting embodiment of the inventive concepts;

FIG. 15 is a diagram of a memory system using a 3D semiconductor memory device, according to another non-limiting embodiment of the inventive concepts; and

FIG. 16 is a block diagram of a computing system using a 3D semiconductor memory device, according to a non-limiting embodiment of the inventive concepts.

### DETAILED DESCRIPTION

The attached drawings are referred to in order to enhance the appreciation of example embodiments of the inventive concepts. Hereinafter, the example embodiments will be described in further detail with reference to the attached drawings. Like reference numerals in the drawings denote like elements.

It will be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on,” “directly connected to,” or “directly coupled to” another element or layer, there are no intervening elements or layers present. Like numbers refer to like elements throughout the specification. As used herein, the term “and/or” includes any and all combinations of one or more of the associated listed items.

It will be understood that, although the terms first, second, third, etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, e.g., “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of example embodiments. As used herein, the singular forms “a,” “an,” and “the” are intended to include the plural forms as well, unless the context clearly indicates otherwise. It will be further understood that the terms, “comprises,” “comprising,” “includes,” and/or “including,” if used herein, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing.

Unless otherwise defined, all terms (including technical and scientific terms) used herein have the same meaning as commonly understood by one of ordinary skill in the art. It will be further understood that terms, including those defined in commonly used dictionaries, should be interpreted as having a meaning that is consistent with their meaning in the context of the relevant art and will not be interpreted in an idealized or overly formal sense unless expressly so defined herein.

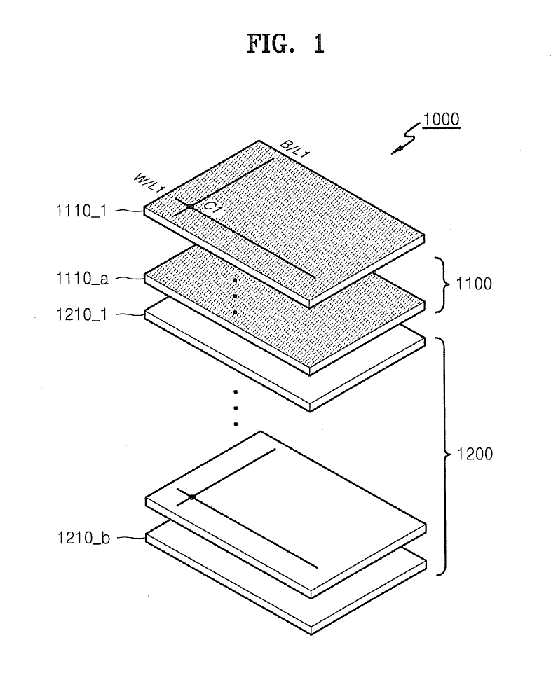

FIG. 1 is a diagram of a 3-dimensional (3D) semiconductor memory device 1000 according to a non-limiting embodiment of the inventive concepts. As shown in FIG. 1, the 3D semiconductor memory device 1000 includes a plurality of semiconductor layers 1110_1 through 1210_{—}b, which may have the same memory structure. Each of the semiconductor layers 1110_1 through 1210_{—}b includes a memory cell array including a plurality of memory cells, bit lines B/L, and word lines W/L. For example, a memory cell C1 is disposed at a point where one bit line B/L1 and one word line W/L1 cross each other.

The 3D semiconductor memory device 1000 includes a first memory region 1100 and a second memory region 1200. The first memory region 1100 may be a region for storing system data. The first memory region 1100 includes the semiconductor layers 1110_1 through 1110_{—}a. In other words, each of the semiconductor layers 1110_1 through 1210_{—}b of FIG. 1 may include a memory cell array, and a part of the memory cell array is set as (or designated as forming) the first memory region 1100 and another part of the memory cell array is set as (or designated as forming) the second memory region 1200. The system data may be at least one piece of data selected from the group consisting of a booting code, a system code, and application software.

The first and second memory regions 1100 and 1200 may be set based on defect characteristics of the semiconductor layers 1110_1 through 1210_{—}b. For example, a semiconductor layer in which a faulty bit is not generated may be set as the first memory region 1100. Here, the faulty bit may not be generated since a defective memory cell is repaired or replaced by a repair technology that supports a repair operation. The repair operation may be performed by using a redundancy region or an error correction code (ECC).

The second memory region 1200 includes the semiconductor layers 1210_1 through 1210_{—}b, which may be for storing data aside from the system data. The data aside from the system data may be at least one piece of data selected from the group consisting of an image, a document, music, a map, and a moving image, which may be formed of a digital media file.

Each of the semiconductor layers 1210_1 through 1210_{—}b of the second memory region 1200 may allow the generation of a faulty bit. In other words, the second memory region 1200 may include the data aside from the system data, and a system may normally operate although a quality of an object may deteriorate when a faulty bit is generated in the second memory region 1200. Accordingly, the second memory region 1200 may include a semiconductor layer having a defective memory cell that cannot be repaired by the repair technology.

The semiconductor layers 1110_1 through 1210_{—}b may be manufactured via the same process. Also, since the first memory region 1100 requires operation stability to store the system data, an operation temperature of the first memory region 1100 may be lower than that of the second memory region 1200. In order to reduce the operation temperature, the first memory region 1100 may be stacked on the second memory region 1200 so that heat of the first memory region 1100 is more readily released.

When the 3D semiconductor memory device 1000 is packaged, a heat emission unit (not shown), such as a heat sink, may be included so that heat generated in the 3D semiconductor memory device 1000 is more readily released. When the heat emission unit is disposed on a package of the 3D semiconductor memory device 1000, the first memory region 1100 may be stacked on the second memory region 1200 so that the heat of the first memory region 1100 is more readily released. Here, the concepts of on and below may not be limited to an absolute meaning. In other words, the first memory region 1100 may be disposed relatively near to the heat emission unit in the 3D semiconductor memory device 1000 so as to readily emit the heat. For example, when the 3D semiconductor memory devices 1000 are packaged upside down, the second memory region 1200 may be stacked on the first memory region 1100 when stacking the semiconductor layers 1110_1 through 1210_{—}b.

The first and second memory regions 1100 and 1200 may be classified based on alternating current (AC) characteristics or direct current (DC) characteristics of the semiconductor layers 1110_1 through 1210_{—}b, instead of (or in addition to) the existence of a faulty bit. For example, since an operating speed of the 3D semiconductor memory device 1000 may increase when the AC characteristics are favorable, semiconductor layers having favorable AC characteristics may be set as the first memory region 1100.

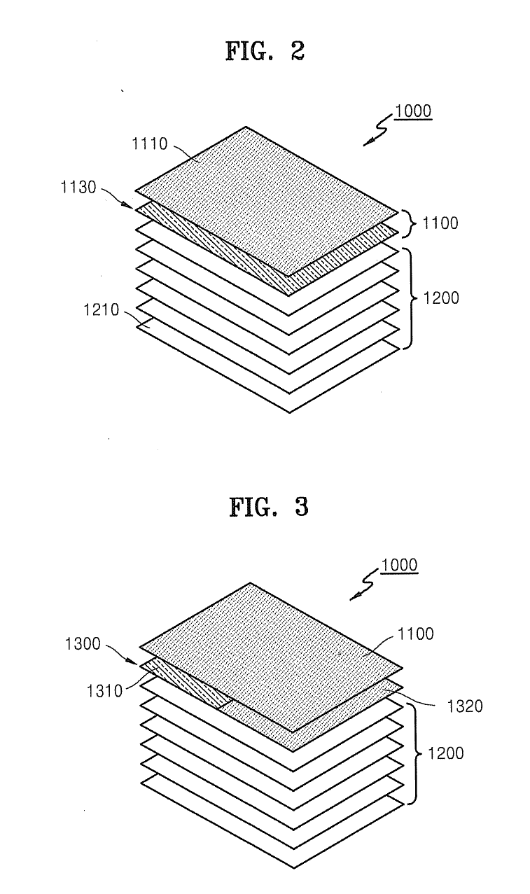

FIG. 2 is a diagram of the 3D semiconductor memory device 1000 of FIG. 1, according to a modified embodiment of the inventive concepts. As shown in FIG. 2, the 3D semiconductor memory device 1000 includes the first memory region 1100 storing system data and the second memory region 1200 storing data aside from the system data. Also, the 3D semiconductor memory device 1000 includes 8 semiconductor layers for storing the system data or the data.

The first memory region 1100 includes semiconductor layers 1110 and 1130. The first memory region 1100 may be a space for storing the system data, and the semiconductor layers 1110 and 1130 included in the first memory region 1100 are assigned as regions for storing the system data.

Specifically, some of the semiconductor layers 1110 and 1130, for example, the semiconductor layer 1110 may be assigned as a region for storing the system data at all times. On the other hand, another of the semiconductor layers 1110 and 1130, for example, the semiconductor layer 1130 may be initially assigned as a region for storing the system data, but may be subsequently changed to a region for storing the data aside from the system data, based on a data storage state. Accordingly, when the system data is not stored in the semiconductor layer 1130 or is stored only in a part of the semiconductor layer 1130, the data aside from the system data may be stored in the semiconductor layer 1130. In other words, when there is space in the semiconductor layer 1130, the data aside from the system data may be stored in the space in the semiconductor layer 1130.

The semiconductor layer 1130 (in which the use is changeable between storing the system data and storing the data aside from the system data) is shown in FIG. 2 as being included in the first memory region 1100. Alternatively, it should be understood that the semiconductor layer 1130 may also be defined as another region, for example, a third memory region.

FIG. 3 is a diagram of the 3D semiconductor memory device of FIG. 1, according to another modified embodiment of the inventive concepts. The 3D semiconductor memory device 1000 includes the first memory region 1100 for storing system data, the second memory region 1200 for storing data aside from the system data, and a third memory region 1300 for storing at least one of the system data and the data aside from the system data according to a data storage state.

Each of semiconductor layers of the 3D semiconductor memory device 1000 may include a plurality of memory blocks. As such, the semiconductor layer of the third memory region 1300 includes a plurality of memory blocks, wherein the usage of a part of the memory blocks, for example, a first block region 1310, and another part of the memory blocks, for example, a second block region 1320 may be different. The usage may be differently set for the first and second block regions 1310 and 1320 based on the existence of a faulty bit in the semiconductor layer of the third memory region 1300. For example, when a faulty bit is generated in a memory block of the semiconductor layer of the third memory region 1300, the corresponding block region may be assigned to store the data aside from the system data. On the other hand, when a faulty bit is not generated in a memory block, the corresponding block region may be assigned to store the system data.

The type of data stored in the memory blocks of the third memory region 1300 may be varied in a manner that would be appropriate. For example, the first block region 1310 may store the data aside from the system data, and the second block region 1320 may store the system data. Alternatively, the first or second block region 1310 or 1320 may be initially assigned to store the system data, and then subsequently changed to store the data aside from the system data according to a data storage state. Accordingly, the third memory region 1300 may store one of the system data and the data aside from the system data, or both the system data and the data aside from the system data.

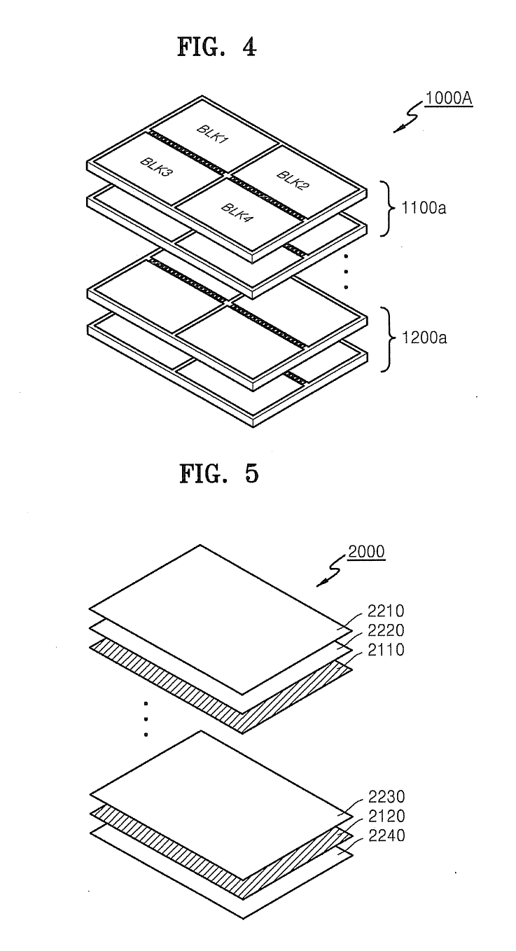

FIG. 4 is a diagram of a 3D semiconductor memory device 1000A wherein the 3D semiconductor memory device 1000 of FIG. 1 is realized as a dynamic random access memory (DRAM). The 3D semiconductor memory device 1000A includes a first memory region 1100a for storing system data, and a second memory region 1200a for storing data aside from the system data, wherein a DRAM is disposed in each stacked semiconductor layer. Each semiconductor layer includes memory blocks BLK1 through BLK4 having a plurality of DRAM cell arrays and peripheral circuits.

Data to be stored in the second memory region 1200a may be relatively large capacity digital image files, and application frequency of the data may not high compared to the system data. Accordingly, a refresh cycle of the second memory region 1200a may be longer than that of the first memory region 1100a, thereby decreasing power consumption of the 3D semiconductor memory device 1000A.

In FIG. 4, each semiconductor layer is shown as including the memory blocks BLK1 through BLK4. Alternatively, a plurality of banks or ranks may be disposed in each semiconductor layer as units of DRAM cell sets. As described above with reference to FIG. 3, when different types of data are stored in one semiconductor layer, the system data may be stored in a part of the banks or ranks, and the data aside from the system data may be stored in another part of the banks or ranks. Alternatively, when a memory having a different cell structure from DRAM is disposed in the semiconductor layer, units of cell sets corresponding to characteristics of the memory, for example, page units, may be applied.

Examples of memory having a different cell structure from DRAM may include a phase change random access memory (PRAM) using a flash and a phase change material, a resistive random access memory (RRAM) using a material having variable resistance characteristics of transition metal oxides, and a magnetic random access memory (MRAM) using a ferromagnetic material. A resistance memory has a resistance value that changes according to a current or voltage and does not require a refresh operation due to a nonvolatile characteristic, wherein the resistance value is maintained even if the supply of the current or voltage is blocked.

FIG. 5 is a diagram of a 3D semiconductor memory device 2000 according to another non-limiting embodiment of the inventive concepts. The 3D semiconductor memory device 2000 may include a first memory region for storing system data and including at least one semiconductor layer, and a second memory region for storing data aside from the system data and including at least one semiconductor layer. For example, the first memory region may include semiconductor layers 2110 and 2120, and the second memory region may include semiconductor layers 2210, 2220, 2230, and 2240.

In FIG. 5, a semiconductor layer from among a plurality of stacked semiconductor layers is not designated in advance to be the first memory region. Instead, the semiconductor layers are first stacked on each other, characteristics of the stacked semiconductor layers are determined, and then some of the semiconductor layers are designated to be the first memory region based on the result of the determination. For example, the semiconductor layers 2110 and 2120, in which a faulty bit is not generated based on a test operation, are designated to be the first memory region, and the remaining semiconductor layers 2210, 2220, 2230, and 2240 are designated to be the second memory region. The test operation may be performed after stacking the semiconductor layers.

A method of programming and storing a layer identification (ID) of each semiconductor layer may be used while setting a memory region of each of the semiconductor layers 2110 and 2120, and 2210 through 2240 of the 3D semiconductor memory device 2000 of FIG. 5. For example, in a system using the 3D semiconductor memory device 2000, a command/address and data may be transmitted to the 3D semiconductor memory device 2000 so that system data is stored in a semiconductor layer corresponding to a layer ID having a predetermined or desired value, from among the semiconductor layers of the 3D semiconductor memory device 2000. Even when locations of the semiconductor layers 2110 and 2120 set as the first memory region are changed based on the result of the test operation, the system data is stored in the first memory region since the layer IDs are programmed and stored for each semiconductor layer. Although not illustrated in FIG. 5, a unit for storing the layer ID may be included in each semiconductor layer of the 3D semiconductor memory device 2000.

Aside from the existence of a faulty bit, an AC characteristic or a DC characteristic of a semiconductor layer may be used to classify the first and second memory regions. For example, since an operating speed of a memory increases when an AC characteristic is favorable, a semiconductor layer having a favorable AC characteristic may be designated as the first memory region.

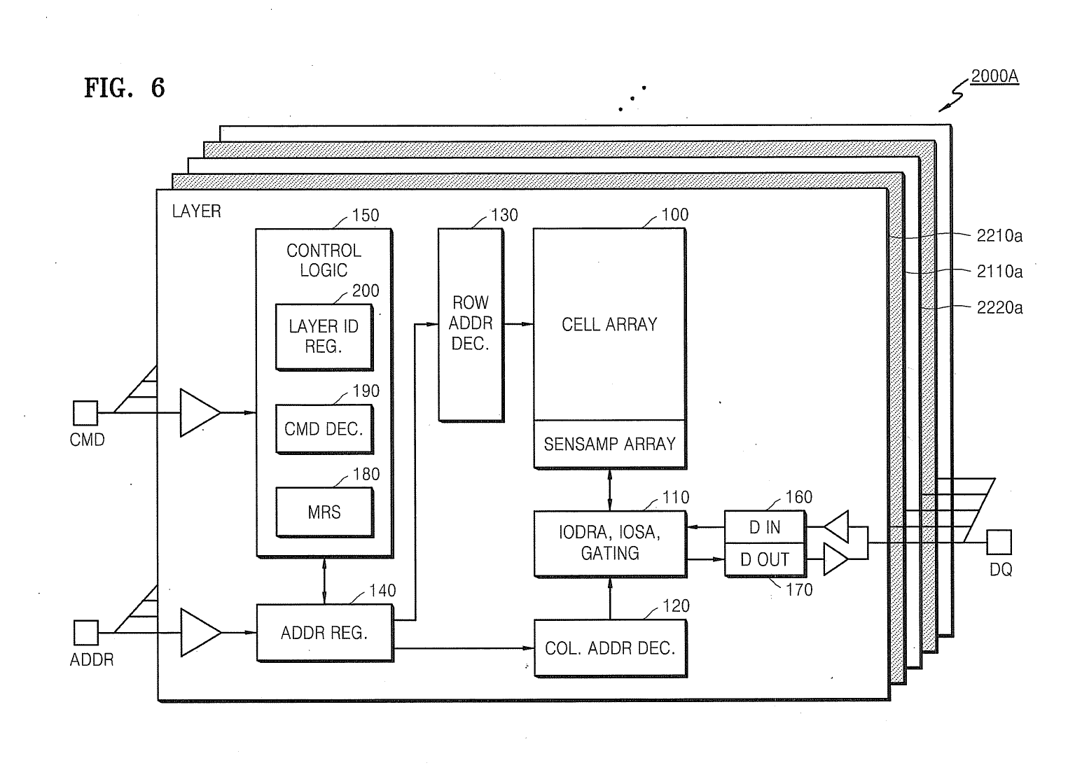

FIG. 6 is a block diagram of semiconductor layers 2110a, 2210a, 2220a of a 3D semiconductor memory device 2000A, according to a non-limiting embodiment of the inventive concepts. The semiconductor layers 2110a, 2210a, 2220a, which are stacked on each other in the 3D semiconductor memory device 2000A, may have the same structure, wherein each of the semiconductor layers 2110a, 2210a, 2220a may include a cell array 100, an input and output driver 110, a column address decoder 120, a row address decoder 130, an address register 140, a control logic 150, a data input unit 160, and a data output unit 170. An address signal ADDR received from a source external to the 3D semiconductor memory device 2000A is stored in the address register 140, and the stored address signal ADDR is transmitted to the column address decoder 120 and the row address decoder 130. The cell array 100 receives write data from the input and output driver 110 or outputs read data to the input and output driver 110, according to a decoding result of the row address decoder 130 and the column address decoder 120.

The control logic 150 includes a mode register set (MRS) 180, a command decoder 190, and a layer ID register 200. The command decoder 190 receives a command CMD from a source external to the 3D semiconductor memory device 2000A and performs a decoding operation, based on a setting of the MRS 180. Also, the layer ID register 200 stores a layer ID of a corresponding semiconductor layer, for example, the semiconductor layer 2210a. Based on a result of setting the layer ID, the semiconductor layer, for example, the semiconductor layer 2210a is determined to be one of the first and second memory regions.

A central processing unit (CPU) (not shown) determines a type of data in a file system level, and provides the data and corresponding command CMD and address signal ADDR to the 3D semiconductor memory device 2000A. The control logic 150 controls input data to be stored in any one of the first and second memory regions by referring to the information stored in the layer ID register 200. Specifically, system data from among data received through the data input unit 160 is stored in at least one semiconductor layer of the first memory region, and data aside from the system data is stored in at least one semiconductor layer of the second memory region. Accordingly, the control logic 150 determines whether the command CMD is related to the storage of the system data or the data aside from the system data by decoding the command CMD, and controls the data to be stored or not stored in the corresponding semiconductor layer by referring to the information stored in the layer ID register 200.

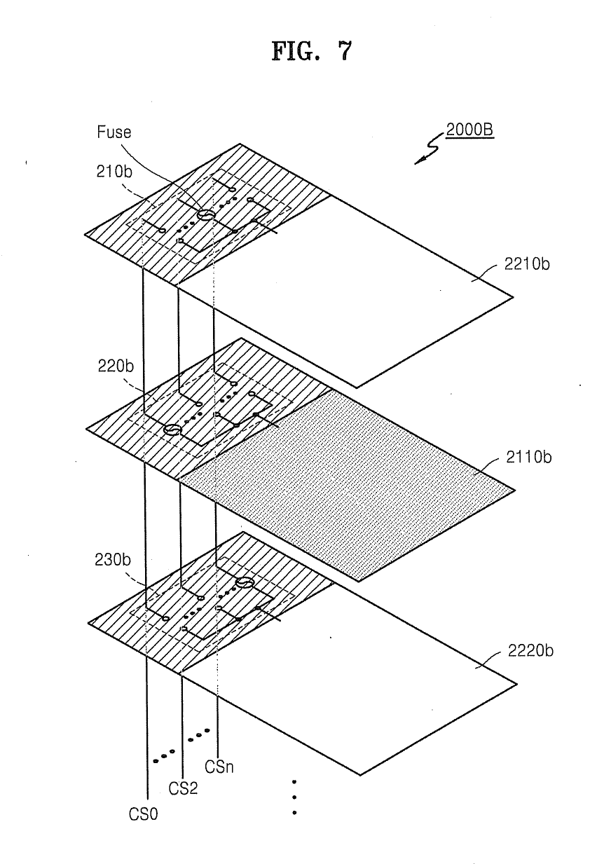

FIG. 7 is a diagram of layer ID registers of the semiconductor layers of FIG. 6, realized as electric fuses. As shown in FIG. 7, each of the semiconductor layers 2110b, 2210b, 2220b of a 3D semiconductor memory device 2000B includes a layer ID register for storing a corresponding layer ID. The 3D semiconductor memory device 2000B includes a first memory region including the semiconductor layer 2110b for storing system data, and a second memory region including the semiconductor layers 2210b and 2220b for storing data aside from the system data. As shown in FIG. 7, the layer ID registers may be realized as electrical fuses (E-fuse) 210b, 220b, and 230b.

A program of the E-fuses 210b through 230b may be controlled by a predetermined or desired fuse controller (not shown) included in the 3D semiconductor memory device 2000B, or an electric signal of an external device, such as a predetermined or desired tester (not shown) for performing a test operation. In FIG. 7, the E-fuses 210b through 230b are commonly controlled by ID control signals CS0 through CSn of an external device, but alternatively, a program control device may be included in any one of or each of the semiconductor layers 2110b, 2210b, 2220b. While programming the E-fuses 210b through 230b, the semiconductor layer 2110b (in which a faulty bit is not generated) may be programmed to be included in the first memory region.

The ID control signals CS0 through CS1 may be connected to the E-fuses for setting the first memory region, while the ID control signals CS2 through CSn may be connected to the E-fuses for setting the second memory region. As shown in FIG. 7, in order to set the semiconductor layer 2110b in which a faulty bit is not generated from among the semiconductor layers 2110b, 2210b, 2220b, an E-fuse connected to the ID control signal CS0 or CS1 from among the E-fuses of the semiconductor layer 2110b is set to be in a conductive state while the other E-fuses are set to be in a cut-off state.

Similarly, in order to set some of the stacked semiconductor layers 2110b, 2210b, 2220b, for example, the semiconductor layer 2210b as the second memory region, any one of E-fuses connected to the ID control signals CS2 through CSn from among the E-fuses of the semiconductor layer 2210b may be set to be in a conductive state while the other E-fuses are set to be in a cut-off state, thereby storing information about a layer ID. Alternatively, instead of using an E-fuse, the layer ID register may be realized using software.

Referring back to FIG. 6, various configurations may be disposed in each of the semiconductor layers 2110a through 2220a. However, some configurations of FIG. 6, for example, the control logic 150, the address register 140, the input and output driver 110, the data input unit 160, and the data output unit 170 may be commonly included in any one of the semiconductor layers 2110a through 2220a including a circuit region. In other words, any one of the semiconductor layers 2110a through 2220a may operate as a master of the 3D semiconductor memory device 2000A, while the remaining semiconductor layers of the semiconductor layers 2110a through 2220a may operate as slaves. Here, the control logic 150, the address register 140, the input and output driver 110, the data input unit 160, and the data output unit 170 may be disposed in the semiconductor layer corresponding to the master.

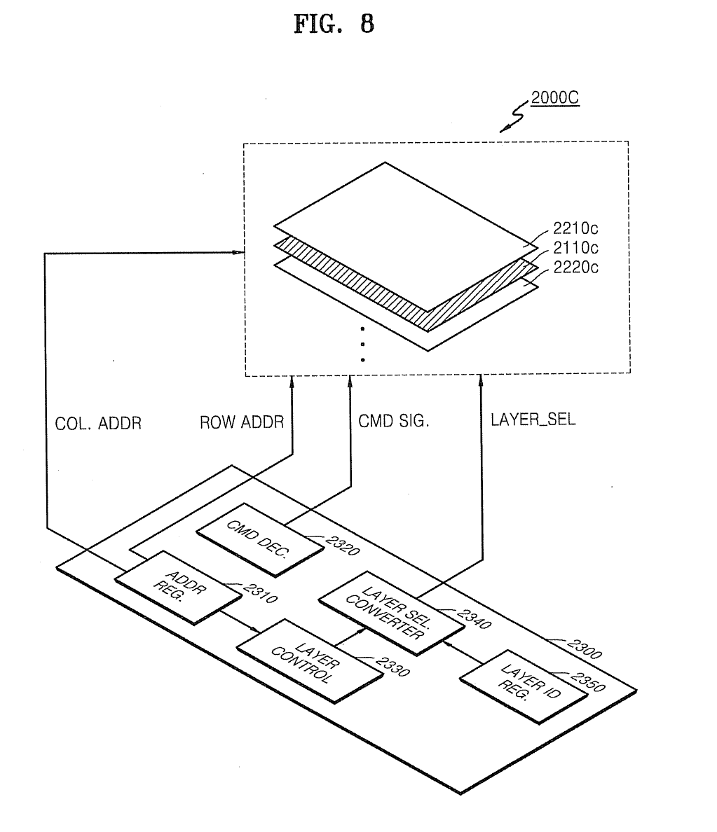

FIG. 8 is a block diagram of semiconductor layers 2110c, 2210c, 2220c, and 2300 of a 3D semiconductor memory device 2000C, according to another non-limiting embodiment of the inventive concepts. As shown in FIG. 8, the 3D semiconductor memory device 2000C includes the semiconductor layers 2110c through 2220c, in which a memory cell array may be disposed, and the semiconductor layer 2300 including a circuit region, in which various circuit blocks for driving the memory cell arrays are disposed. The semiconductor layer 2300 including the circuit region operates as a master, while the other semiconductor layers 2110c through 2220c operate as slaves in the 3D semiconductor memory device 2000C. Although not shown in FIG. 8, the semiconductor layer 2300 including the circuit region may further include a memory cell array for storing data, and may be set as any one of first and second memory regions. In further detail, the semiconductor layer 2300 may be disposed at the bottom from among the semiconductor layers 2300 and 2110c through 2220c in the 3D semiconductor memory device 2000C. Also, a first memory region for storing system data may include the semiconductor layer 2110c, while a second memory region for storing data aside from the system data may include the semiconductor layers 2210c and 2220c.

The circuit region included in the semiconductor array 2300 may include various configurations as shown in FIG. 6. For example, the circuit region may include an address register 2310, a command decoder 2320, a layer controller 2330, a layer selection converter 2340, and a layer ID register 2350. In FIG. 8, the command decoder 2320 and the layer ID register 2350 are shown as different circuit blocks. Alternatively, the command decoder 2320 and the layer ID register 2350 may be included in the same control logic as shown in FIG. 6.

Addresses stored in the address register 2310 may be column and row addresses, and are provided to the semiconductor layers 2110c through 2220c. Also, the layer controller 2330 generates a layer selection signal for selecting the semiconductor layers 2110c through 2220c by referring to the addresses or some bits of the addresses. The layer ID register 2350 stores layer IDs of the semiconductor layers 2110c through 2220c, wherein the layer IDs are set in such a way that each of the semiconductor layers 2110c through 2220c is included in the first or second memory regions based on a result of testing a faulty bit.

The layer selection converter 2340 receives a layer selection signal from the layer controller 2330, and performs a conversion operation on the layer selection signal by referring to information stored in the layer ID register 2350. For example, when a predetermined or desired semiconductor layer is designated to be the first memory region according to a test result, a layer ID of the predetermined or desired semiconductor layer is stored in the layer ID register 2350. Then, when it is determined that the layer selection signal from the layer controller 2330 is a signal for selecting a semiconductor layer included in the second memory region while storing the system data, the conversion operation is performed on the layer selection signal. Such a converted layer selection signal (layer_sel) is provided to the semiconductor layers 2110c through 2220c, and the predetermined or desired semiconductor layer included in the first memory region stores the system data in response to the converted layer selection signal (layer_sel).

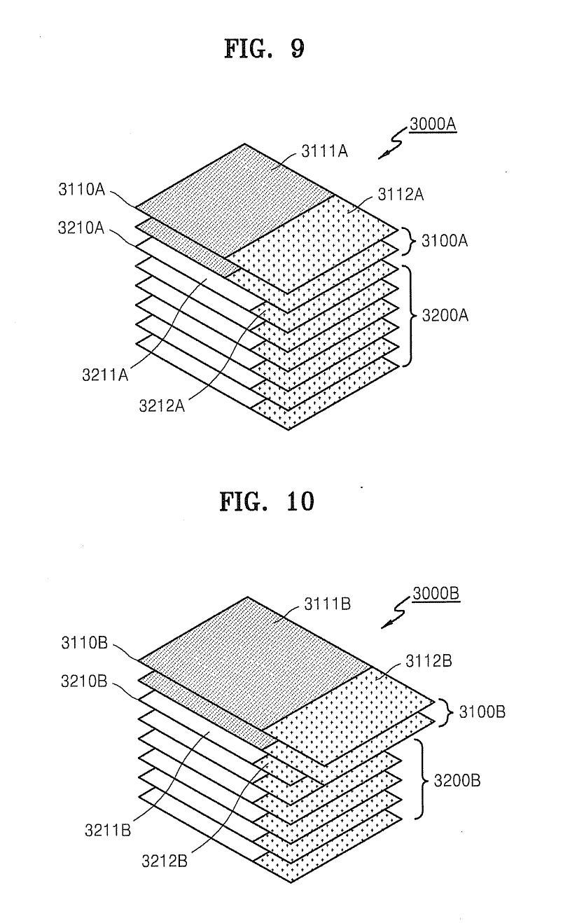

FIGS. 9 and 10 are diagrams of 3D semiconductor memory devices 3000A and 3000B according to other non-limiting embodiments of the inventive concepts.

The 3D semiconductor memory device 3000A of FIG. 9 includes a first memory region 3100A for storing system data, and a second memory region 3200A for storing data aside from the system data. Each of the first and second memory regions 3100A and 3200A includes at least one semiconductor layer. Characteristics of the 3D semiconductor memory device 3000A of FIG. 8 will be described with reference to semiconductor layers 3110A and 3210A, which are the respective semiconductor layers of the first and second memory regions 3100A and 3200A.

Each of semiconductor layers may include a normal cell array and a redundancy cell array. For example, the semiconductor layer 3110A of the first memory region 3100A includes a normal cell array 3111A and a redundancy cell array 3112A. Also, the semiconductor layer 3210A of the second memory region 3200A includes a normal cell array 3211A and a redundancy cell array 3212A. The redundancy cell arrays 3112A and 3212A are respectively disposed to repair or replace defects of normal cell arrays 3111A and 3211A.

Here, the redundancy cell array 3112A of the first memory region 3100A may have a size that is sufficient to repair all defective memory cells that may be generated in the normal cell array 3111A. As shown in FIG. 9, a size of the redundancy cell array 3112A of the first memory region 3100A is larger than a size of the redundancy cell array 3212A of the second memory region 3200A. Stated differently, a ratio of sizes of the redundancy cell array 3112A to the normal cell array 3111A of the first memory region 3100A may be higher than a ratio of sizes of those of the second memory region 3200A. Such a larger size or higher ratio may increase a probability of repairing a defective memory cell generated in the first memory region 3100A, and eventually, all bits in the first memory region 3100A may be pass bits.

In order for all memory cells of the first memory region 3100A to be pass bits, the redundancy cell array 3112A may repair a defect in a bit unit. On the other hand, the redundancy cell array 3212A of the second memory region 3200A may repair a defect in a row unit or column unit.

In FIG. 10, the sizes of the semiconductor layers 3110E and 3210B of the first and second memory regions 3100B and 3200B are different from each other. The 3D semiconductor memory device 3000B includes the first memory region 3100B for storing system data and the second memory region 3200B for storing data aside from the system data.

Each of stacked semiconductor layers may include a normal cell array and a redundancy cell array. A size of a redundancy cell array 3112B of the first memory region 3100B is larger than a size of a redundancy cell array 3212B of the second memory region 3200B. Stated differently, a ratio of a redundancy cell array 3112B to the normal cell array 3111B of the first memory region 3100B may be higher than that of the second memory region 3200B. Also, since the semiconductor layer 3110B of the first memory region 3100B is larger than the semiconductor layer 3210B of the second memory region 3200B, even when the redundancy cell array 3112B of the first memory region 3100B is larger than the redundancy cell array 3212B of the second memory region 3200B, the size of the normal cell array 3111B of the first memory region 3100B may be identical to a size of a normal cell array 3211B of the second memory region 3200B.

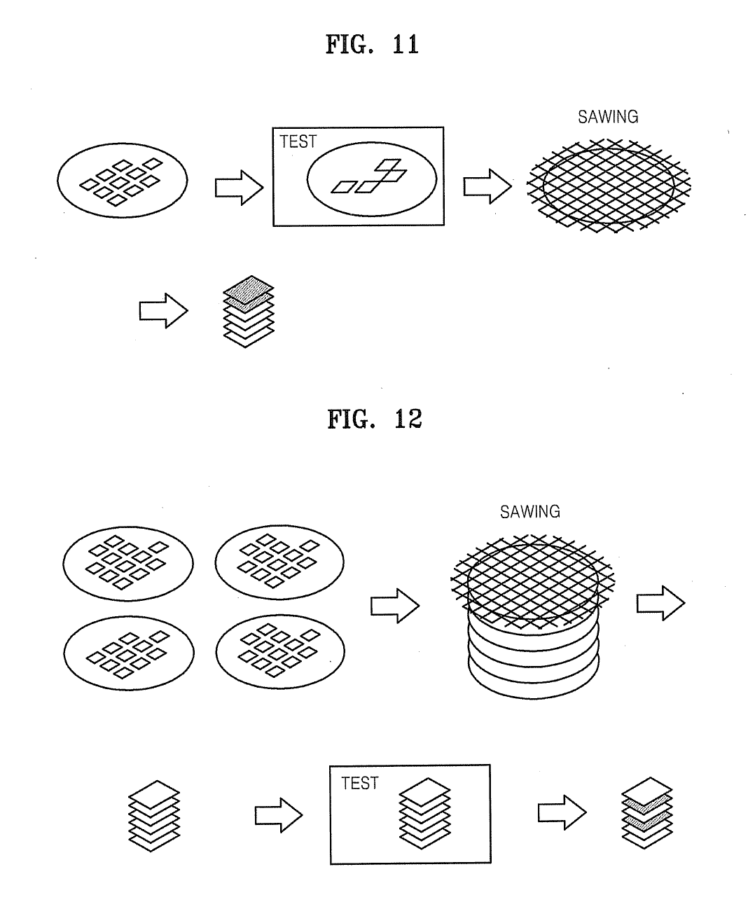

FIGS. 11 and 12 are diagrams of methods of manufacturing a 3D semiconductor memory device, according to non-limiting embodiments of the inventive concepts.

Semiconductor layers of a 3D semiconductor memory device may be referred to as dies. In a semiconductor manufacturing process, a die may be a piece of wafer to which a circuit forming a memory is integrated before being packaged. Generally, a memory device is tested so as to only use a die without a faulty bit.

However, according to a non-limiting embodiment of the inventive concepts, a die having a faulty bit may be used as a semiconductor layer of a second memory region of a 3D semiconductor memory device. Accordingly, a yield of a semiconductor is increased, thereby reducing manufacturing costs and increasing productivity. Here, a first die may denote a die without a faulty bit, and a second die may denote a die in which a faulty bit is present but does not affect the storage of data aside from system data. Examples of a method of stacking a 3D memory will now be described.

FIG. 11 is a diagram of a method of manufacturing the 3D semiconductor memory device 1000 of FIG. 1. The 3D semiconductor memory device 1000 may also be referred to as a die stack, wherein dies having less defects are selected and stacked on each other.

In further detail, dies manufactured on a wafer may each be tested to identify/select a first die without a defect, a second die having a faulty bit, and a die that cannot be used. Then, the wafer may be sawed so as to be divided into individual dies. Here, the first die may be disposed in a first memory region for storing system data, and the first or second die may be disposed in a second memory region for storing data aside from the system data. The first die in the first memory region may be stacked so as to be a top die of the 3D semiconductor memory device 1000, and at least one of the first and second dies may be stacked below the first memory region, as the second memory region. Such stacked first and second dies may operate as semiconductor layers of the 3D semiconductor memory device 1000. A layer ID of each semiconductor layer may be programmed and stored in the 3D semiconductor memory device 1000, or stored by using an E-fuse disposed on each semiconductor layer.

FIG. 12 is a diagram of a method of manufacturing the 3D semiconductor memory device 2000 of FIG. 5. The 3D semiconductor memory device 2000 may also be referred to as a wafer stack, wherein wafers, on which a plurality of dies are formed, may be stacked on each other and sawed. Unlike a die stack, each of stacked semiconductor layers of the 3D semiconductor memory device 2000 is tested in the wafer stack. Some of the stacked semiconductor layers without a faulty bit may be designated to be a first memory region. Also, others of the stacked semiconductor layers with or without a faulty bit may be designated as a second memory region. In FIG. 11, since the first memory region is the top stacked semiconductor layer(s), the first memory region may be accessed by providing an address corresponding to a semiconductor layer at the top when the 3D semiconductor memory device 1000 is accessed externally. In FIG. 12, since a location of some of the stacked semiconductor layers corresponding to the first memory region may change based on a result of testing the stacked semiconductor layers, a layer ID register, as described above, may be used to store the location of the semiconductor layers.

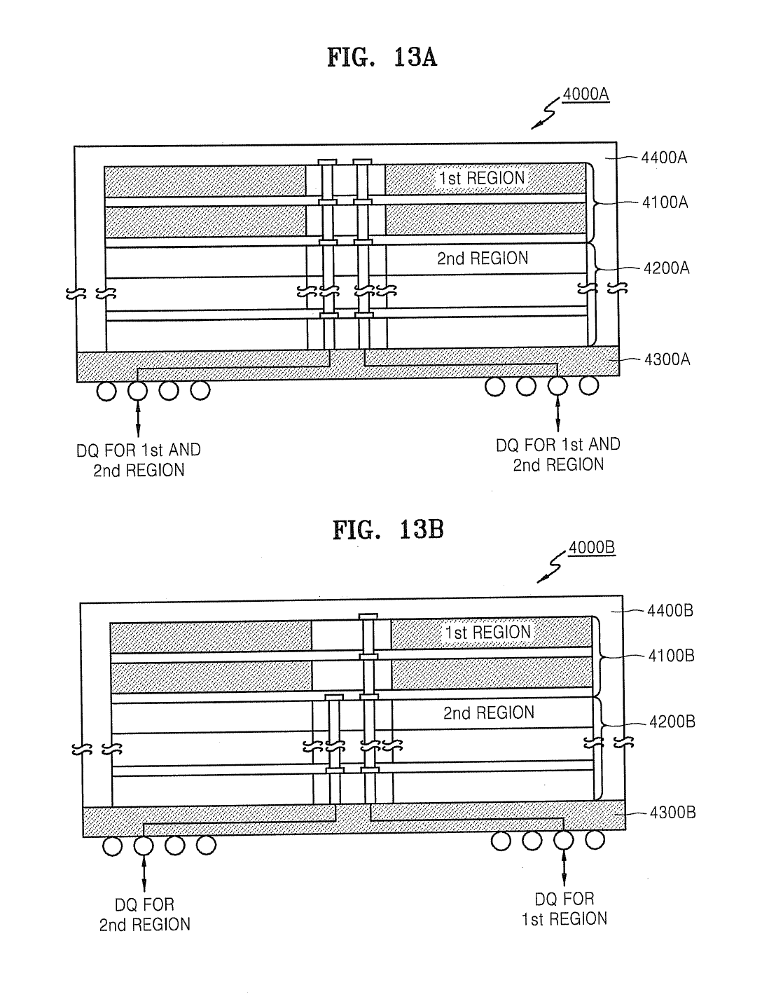

FIGS. 13A and 13B are diagrams of packaged 3D semiconductor memory devices 4000A and 4000B according to non-limiting embodiments of the inventive concepts. In FIGS. 13A and 13B, signals provided to semiconductor layers of the packaged 3D semiconductor memory devices 4000A and 4000B may be transmitted through through-silicon vias (TSVs).

As shown in FIG. 13A, the packaged 3D semiconductor memory device 4000A includes a plurality of semiconductor layers, each being a first memory region 4100A or a second memory region 4200A. In order to package the 3D semiconductor memory device 4000A, a substrate 4300A including a conductive unit, such as a solder ball, on one surface and the semiconductor layers on the other surface, and a molding unit 4400A for protecting the semiconductor layers are further included.

As described above, the first and second memory regions 4100A and 4200A may store different types of data. Also, data may be transmitted to and from an external controller (not shown) through the TSV disposed in each semiconductor layer and the solder ball disposed on one surface of the substrate 4300A. In FIG. 13A, the data of the first and second memory regions 4100A and 4200A may be transmitted and received to and from the external controller through the same path. For example, in FIG. 13A, the data of the first and second memory regions 4100A and 4200A may be transmitted through the same TSV and the same solder ball.

In the packaged 3D semiconductor memory device 4000B of FIG. 13B, the first and second memory regions 4100B and 4200B may transmit and receive data to and from an external controller through different paths. The packaged 3D semiconductor memory devices 4000B includes a plurality of semiconductor layers, each being the first memory region 4100B or the second memory region 4200B. Also, a substrate 4300B including a conductive unit, such as a solder ball, on one surface and the semiconductor layers on the other surface, and a molding unit 4400B for protecting the semiconductor layers are further included.

The first memory region 4100B may store at least one piece of system data selected from the group consisting of a booting code, a system code, and application software, may have a relatively high access frequency, and may require stable signal transmission. Accordingly, a path for transmitting data of the first memory region 4100B may be separated from a path for transmitting data of the second memory region 4200B. For example, in FIG. 13B, a TSV for the first memory region 4100B and a TSV for the second memory region 4200B are separately disposed in the semiconductor layers so as to form different signal paths, and solder balls for externally transmitting the data of the first and second memory regions 4100B and 4200B may be separately disposed according to the TSVs. Although not shown in FIG. 13B, the first and second memory regions 4100B and 4200B may use different conductive units to transmit the data so that the paths for transmitting the data of the first and second memory regions 4100B and 4200B are further distinguished from each other. For example, the data of the first memory region 4100B may be transmitted by using the TSV, and the data of the second memory region 4200B may be transmitted by using another unit, such as a conductive wire.

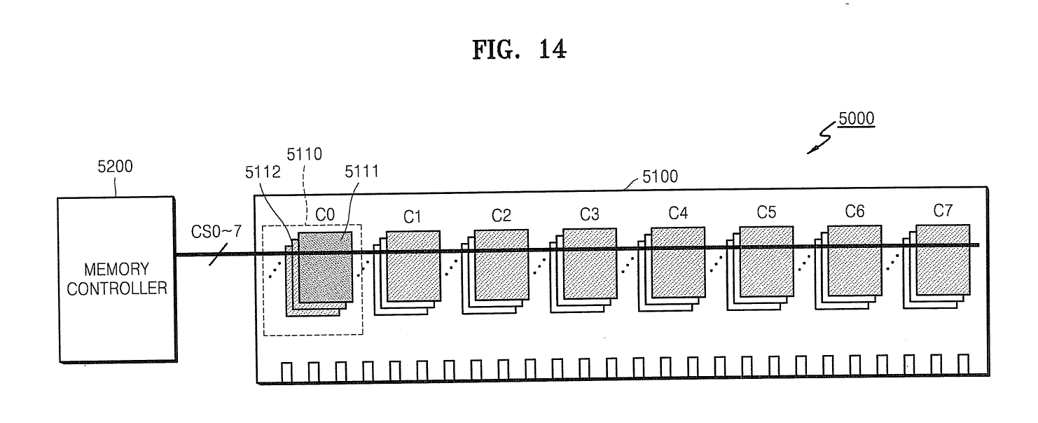

FIG. 14 is a diagram of a memory system 5000 including a memory module 5100 in which at least one 3D semiconductor memory device 5110 is disposed, according to a non-limiting embodiment of the inventive concepts.

The memory system 5000 includes the memory module 5100 and a memory controller 5200. The memory controller 5200 transmits memory device selection signals C0 through C7 to the memory module 5100. One or more 3D semiconductor memory devices 5100 having the same structure may be disposed in the memory module 5100. For example, when eight (8) 3D semiconductor memory devices 5110 are disposed, a memory operation may be controlled by setting an order from C0 to C7. A plurality of semiconductor layers having the same memory structure may be stacked in the 3D semiconductor memory device 5110. Also, each 3D semiconductor memory device 5110 includes a first memory region 5111 for storing system data and including at least one semiconductor layer, and a second memory region 5112 for storing data aside from the system data and including at least one semiconductor layer. Also, each of the 3D semiconductor memory devices 5110 may be any of the 3D semiconductor memory devices described herein.

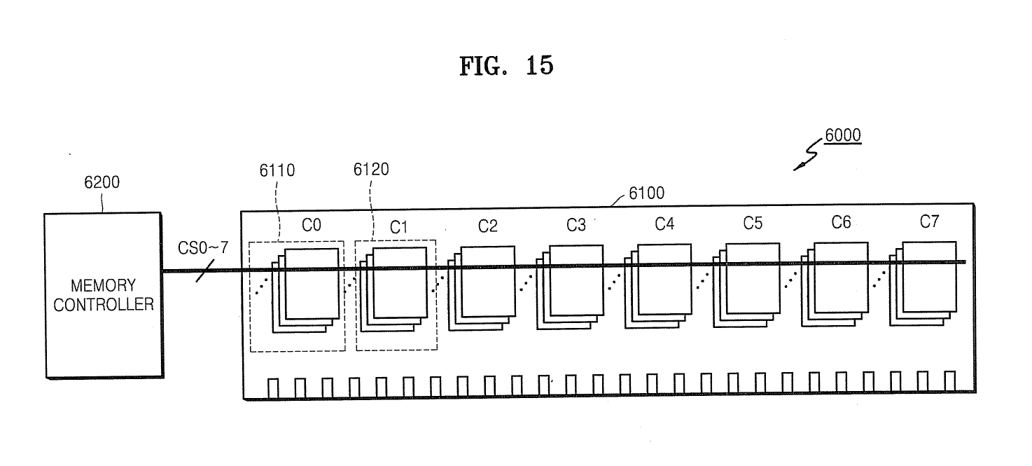

FIG. 15 is a diagram of a memory system 6000 according to another non-limiting embodiment of the inventive concepts. The memory system 6000 includes a memory module 6100 and a memory controller 6200. The memory controller 6200 transmits memory device selection signals C0 through C7 to the memory module 6100. 3D semiconductor memory devices 6110 and 6120 may be disposed in the memory module 6100. For example, when eight (8) 3D semiconductor memory devices are disposed, a memory operation may be controlled by setting an order from C0 to C7.

The memory module 6100 of FIG. 15 may be an example of a 3D semiconductor memory device described above and extended as a module concept. In other words, like a 3D semiconductor memory device which includes a first memory region for storing system data, and a second memory region for storing data aside from the system data, a part of the 3D semiconductor memory devices of a memory module may be set as a first memory region, and another part of the 3D semiconductor memory devices may be set as a second memory region. In FIG. 15, the 3D semiconductor memory device 6110 of the memory module 6100 may be set as a first memory region for storing system data, and the remaining seven (7) 3D semiconductor memory devices 6120 may be set as a second memory region for storing data aside from the system data. However, such setting of the first and second memory regions is not limited thereto.

The first memory region may include the 3D semiconductor memory device 6110 including at least one semiconductor layers without a faulty bit, and the second memory region may include the 3D semiconductor memory device 6120 including at least one semiconductor layer having a partial faulty bit but that does not affect the storage of the data aside from the system data. Also, semiconductor layers having the same memory structure may be stacked in each of the 3D semiconductor memory devices 6110 and 6120.

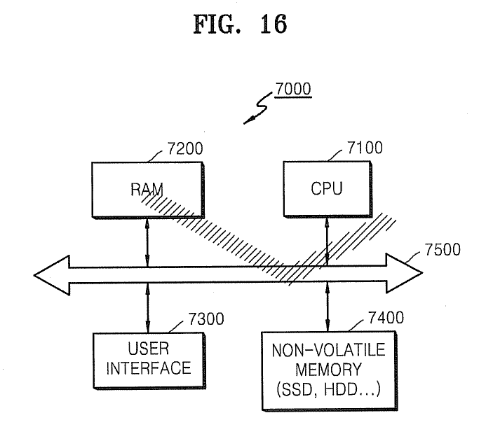

FIG. 16 is a block diagram of a computing system 7000 using a 3D semiconductor memory device, according to a non-limiting embodiment of the inventive concepts. A 3D semiconductor memory device of the inventive concepts may be installed as a RAM 7200 in an information processing system, such as a mobile device or a desktop.

The computing system 7000 includes a central processing unit (CPU) 7100, the RAM 7200, a user interface 7300, and a nonvolatile memory 7400, which are electrically connected to each other via a bus 7500. The nonvolatile memory 7400 may be a relatively large capacity storage device, such as a solid state disk (SSD) or a hard disk drive (HDD).

As described above, the RAM 7200 of the computing system 7000 may be realized as a relatively large capacity 3D semiconductor memory device including a first memory region for storing system data and a second memory region for storing data aside from the system data. Also, the RAM 7200 may use a device, such as an E-fuse, to store a layer ID of a memory region or each semiconductor layer. Accordingly, the RAM 7200 may store digital image data that was stored in a general SSD or HDD, aside from the system data. The CPU 7100 classifies and transmits the system data and the data aside from the system data in a file system level to the RAM 7200, and transmits an address corresponding to each type of data to the RAM 7200 so that the system data and the data aside from the system data are stored in different memory regions of the RAM 7200. The RAM 7200 stores the received data in a semiconductor layer corresponding to the address, by referring to the address and a layer ID stored in the address.

As such, since the system data and the data aside from the system data are stored in the RAM 7200, an operating speed of reading data from the CPU 7100 may be increased. Also, when the RAM 7200 to be installed in the computing system 7000 is manufactured, a plurality of semiconductor layers may be classified into first and second memory regions, and a faulty bit is allowed in semiconductor layers classified as the second memory region. Thus, even when a faulty bit is generated in a part of the semiconductor layers, a corresponding 3D semiconductor memory device may still be usable, thereby improving a process yield. The computing system 7000 may be installed in a mobile device, such as a desktop, a laptop, and a mobile phone.

While the inventive concepts has been particularly shown and described with reference to example embodiments thereof, it will be understood that various changes in form and details may be made therein without departing from the spirit and scope of the following claims.

1. A 3-dimensional (3D) semiconductor memory device comprising:
a plurality of semiconductor layers stacked on each other and having a same memory cell structure, the plurality of semiconductor layers divided into at least a first memory region and a second memory region, the first memory region including at least one semiconductor layer of the plurality of semiconductor layers and configured to store system data, the second memory region including at least one semiconductor layer of the plurality of semiconductor layers and configured to store non-system data, the system data including at least one piece of data selected from the group consisting of a booting code, a system code, and application software.

2. The 3D semiconductor memory device of claim 1, wherein the non-system data includes at least one piece of data for a digital media file and is selected from the group consisting of a still image, a document, music, a map, and a moving image.

3. (canceled)

4. The 3D semiconductor memory device of claim 1, wherein a faulty bit is not present in the at least one semiconductor layer of the first memory region.

5. The 3D semiconductor memory device of claim 1, wherein each of the plurality of semiconductor layers includes a normal cell array and a redundancy cell array configured such that a defective memory cell in the normal cell array of the at least one semiconductor layer of the first memory region is replaced by the redundancy cell array.

6. The 3D semiconductor memory device of claim 1, wherein the at least one semiconductor layer of the second memory region allows an acceptable number of faulty bits.

7. The 3D semiconductor memory device of claim 1, wherein the first memory region is stacked on the second memory region.

8. The 3D semiconductor memory device of claim 1, wherein each of the plurality of semiconductor layers includes a plurality of memory blocks.

9. The 3D semiconductor memory device of claim 1, further comprising:
a third memory region including at least one semiconductor layer of the plurality of semiconductor layers, the third memory region including a space in which the system data is not stored, and the non-system data is stored in the space.

10. The 3D semiconductor memory device of claim 1, further comprising:
a third memory region including at least one semiconductor layer of the plurality of semiconductor layers, wherein the at least one semiconductor layer of the third memory region includes a plurality of memory blocks, a part of the plurality of memory blocks of the third memory region configured to store the system data, and another part of the plurality of memory blocks of the third memory region configured to store the non-system data.

11. The 3D semiconductor memory device of claim 1, wherein the memory cell structure includes a dynamic random access memory (DRAM) cell.

12-18. (canceled)

19. A 3-dimensional (3D) semiconductor memory device having a stacked structure, the 3D semiconductor memory device comprising:
a first memory region including at least one semiconductor layer configured to store system data; and
a second memory region including at least one semiconductor layer configured to store non-system data, each of the at least one semiconductor layers of the first and second memory regions including a normal cell array and a redundancy cell array, and a ratio of the redundancy cell array to the normal cell array of the at least one semiconductor layer of the first memory region being higher than that of the second memory region.

20. The 3D semiconductor memory device of claim 19, wherein a size of the redundancy cell array of the at least one semiconductor layer of the first memory region is larger than that of the second memory region.

21. The 3D semiconductor memory device of claim 19, wherein a defective memory cell in the normal cell array of the at least one semiconductor layer of the first memory region is replaced by the redundancy cell array of the first memory region.

22-29. (canceled)

30. A 3-dimensional (3D) semiconductor memory device comprising:
a plurality of stacked semiconductor layers grouped into at least a first memory region and a second memory region, a first number of the plurality of stacked semiconductor layers forming the first memory region and configured to store system data, a second number of the plurality of stacked semiconductor layers forming the second memory region and configured to store non-system data, and a faulty bit not being present in the first number of the plurality of stacked semiconductor layers designated as forming the first memory region.

31. The 3D semiconductor memory device of claim 30, wherein the plurality of stacked semiconductor layers have a same memory cell structure.

32. The 3D semiconductor memory device of claim 30, wherein the second number of the plurality of stacked semiconductor layers forming the second memory region includes a faulty bit.

33. The 3D semiconductor memory device of claim 30, wherein the first number of the plurality of stacked semiconductor layers forming the first memory region and the second number of the plurality of stacked semiconductor layers forming the second memory region each include a normal cell array and a redundancy cell array.

34. A memory module comprising the 3D semiconductor memory device of claim 30.

35. A memory system comprising:
a memory controller; and
the memory module of claim 34.

36. A computer system comprising:
a central processing unit;
a nonvolative memory device; and
the 3D semiconductor memory device of claim 30.
